(19) United States
(12) Patent Application Publication
(10) Pub. No.: US 2025/0280505 A1
(43) Pub. Date: Sep. 4, 2025

(54) COMPUTING DEVICE AND COMPUTING NODE

(71) Applicant: xFusion Digital Technologies Co., Ltd., Zhengzhou (CN)

(72) Inventor: Chenglong WANG, Zhengzhou (CN)

(21) Appl. No.: 19/203,625

(22) Filed: May 9, 2025

Related U.S. Application Data
(63) Continuation of application No. PCT/CN2023/117105, filed on Sep. 5, 2023.

(30) Foreign Application Priority Data
Nov. 10, 2022 (CN) 202211405995.0

(51) Int. Cl. H05K 7/14

(52) U.S. Cl. CPC H05K 7/1487; H05K 7/1489; H05K 7/1491

(57) ABSTRACT

A computing node includes a housing. The housing includes two side plates that are disposed opposite to each other in a horizontal direction. Each of the two side plates is provided with a plurality of rolling assemblies, and each rolling assembly is capable of rolling in a same rolling plane. The housing includes a bottom plate having a bottom support surface. The bottom support surface and the rolling plane are coplanar, or, in a vertical direction, the bottom support surface is lower than the rolling plane.

### CROSS REFERENCE TO RELATED APPLICATIONS

This application is a continuation of International Application No. PCT/CN2023/117105, filed on Sep. 5, 2023, which claims priority to Chinese Patent Application No. 202211405995.0, filed on Nov. 10, 2022. The disclosures of the aforementioned applications are hereby incorporated by reference in their entireties.

### TECHNICAL FIELD

Embodiments of the present application relates to the field of computing device technology, and in particular to a computing device and a computing node.

### BACKGROUND

A computing device, such as a server, includes a cabinet and a computing node. The computing node is slidably inserted into the cabinet, allowing for convenient mounting and maintenance of the computing node.

In the related art, drawer slides are arranged on both left and right sides of the computing node, respectively, to achieve sliding assembly of the computing node. However, unlike a general drawer, the computing node has the characteristics of considerable weight and large size along an insertion direction. During long-term use, the drawer slides are prone to damage, leading to issues such as sticking during sliding, poor sliding of the computing node, and difficult to push and pull, which severely affects usability of the computing device.

Therefore, it is still a technical problem to be solved for those skilled in the art how to provide a solution to better overcome or alleviate the above defects.

### SUMMARY

Embodiments of the present application provide a computing device and a computing node. The computing node is equipped with a rolling assembly, allowing for simple and effortless operation, and having a relatively long service life. In addition, when the computing node is unassembled, the computing mode can be stably placed on an operating table or desk, which is also conducive to protection of the computing node.

In a first aspect, embodiments of the present application provide a computing node. The computing node may be a server node and the like. The computing node includes a housing. The housing includes two side plates that are disposed opposite to each other in a horizontal direction. Each of the two side plates is provided with a plurality of rolling assemblies, and each of the rolling assemblies is capable of rolling in a same rolling plane. The housing includes a bottom plate having a bottom support surface. The bottom support surface and the rolling plane are coplanar. Or, in a vertical direction, the bottom support surface is lower than the rolling plane.

In an embodiment, the housing of the computing node is provided with a rolling assembly, and the computing node may be assembled by the rolling assembly to achieve a push-pull operation of the computing node. Compared with a conventional drawer slide solution, the rolling assembly in the solution has a simpler structure and is less prone to damage, offering higher reliability and ensuring normal operation of the computing node within a longer period. In addition, compared with a sliding solution, force that drives the rolling assembly to roll in the solution may be smaller, thereby facilitating pushing and pulling the computing node.

In addition, in the vertical direction, the bottom support surface may be lower than the rolling plane, so that when the computing node is placed on the desk or the operating table, the rolling assembly is not in contact with the desk or the operating table, which is conducive to ensuring stable placement of the computing node. Alternatively, the bottom support surface and the rolling plane may also be coplanar. In an embodiment, when the computing node is placed on the desk or the operating table, although the rolling assembly is in contact with the desk or the operating table, the housing may still be stably placed due to static friction between the bottom support surface and the desk or the operating table.

In an embodiment, the bottom plate has a bottom wall surface, the bottom wall surface includes a bottom support surface and two offset surfaces, the two offset surfaces are located on two horizontal sides of the bottom support surface, the bottom support surface is lower than the offset surfaces, and the rolling plane is lower than the offset surfaces.

It should be understood that the computing node provided in the embodiments of the present application may be mounted in the cabinet. In order to accommodate mounting of the computing node, a mounting member is provided in the cabinet. The rolling assembly may roll on the mounting member to achieve the mounting or removal of the computing node. The configuration of the offset surfaces allows for avoidance between the housing and the mounting member, so that space inside the cabinet can be better utilized to accommodate the housing, thereby enhancing integration of the device. Moreover, the configuration also facilitates a larger housing size to increase an internal capacity of the housing, so that the housing can accommodate more or larger electronic components. This can improve a computing capability of the computing node.

In an embodiment, the housing is provided with a groove, the rolling assembly includes a roller, and the roller is mounted in the groove. In this way, the rolling assembly occupies less horizontal space of the computing node, allowing the housing to be made larger in a horizontal direction. Accordingly, the internal capacity of the housing can be increased, and a quantity or size of the electronic components that can be accommodated in the housing can be increased. This, in turn, can improve the computing capability of the computing node.

The rolling assembly may also include a roller shaft on which the roller may be mounted, and the rolling assembly may be mounted by the roller shaft.

In an embodiment, the groove has a lower end opening and a side end opening, the side end opening is located on a horizontal outer wall surface of the side plate, and the lower end opening is located on the offset surface. During actual assembly, the rolling assembly may enter the interior of the groove through the side end opening and be mounted on the side plate, allowing for convenient mounting.

In an embodiment, a horizontal dimension of the roller is less than or equal to that of the groove; and in a horizontal direction, the roller is assembled in the groove. In this way, the roller does not protrude from the horizontal outer wall surface of the side plate in the horizontal direction, and arrangement of the roller does not occupy horizontal space of the housing, which can maximize the internal capacity of the housing, facilitate mounting of more electronic components or larger electronic components, and further improve performance of the computing node.

In an embodiment, the groove has only a lower end opening, and the lower end opening is located on each of the offset surfaces. In this case, mounting of the rolling assembly does not occupy horizontal space of the housing, which can increase the internal capacity of the housing, facilitate the mounting of more electronic components or larger electronic components, and further improve the performance of the computing node.

In an embodiment, the housing may have a main cavity and an accommodation space that are isolated from each other. The main cavity may be used for mounting an electronic component in the form of a processor and is filled with a cooling working medium to achieve cooling of the electronic component. The computing node has a plugging direction, and the accommodation space is located on one side of the main cavity in the plugging direction, and is configured with an external connection component. The external connection component may be used to be connected to the electronic component in the main cavity, or may be in communication with the cooling work medium in the main cavity.

By adopting the solution, a housing wall plate of the housing can protect the external connection component in the accommodation space, which can reduce damage to the external connection component during transportation and handling, and can also improve structural strength of the entire housing. An appearance design of the housing is also neater.

In an embodiment, the accommodation space includes a power signal chamber and a high-speed signal chamber that are isolated from each other, the external connection component includes a power cable and a high-speed signal cable, the power cable is disposed in the power signal chamber, and a rear wall of the power signal chamber is provided with a power connector, the high-speed signal cable is disposed in the high-speed signal chamber, and a rear wall of the high-speed signal chamber is provided with a high-speed signal connector. The rear wall of the power signal chamber and the rear wall of the high-speed signal chamber may be an integrated structure to enhance structural strength of the computing node, or the rear wall of the power signal chamber and the rear wall of the high-speed signal chamber may also be a split structure.

The main cavity is filled with the cooling working medium, and the accommodation space is further provided with a working medium inlet pipe and a working medium outlet pipe for realizing the cooling working medium entering and exiting the main cavity.

In an embodiment, the housing may have an avoidance portion on two plate bodies that are disposed opposite to each other in a vertical direction. The avoidance portion is used to provide avoidance for the working medium inlet pipe and the working medium outlet pipe. Thus, a size of the housing in the vertical direction can be reduced. The avoidance portion may be a hole-type structure that penetrates a corresponding plate body in the vertical direction, or may be a groove-type structure that does not penetrate the corresponding plate body in the vertical direction.

The accommodation space may also be provided with an insertion guide assembly for guiding the mounting of the computing node inside the cabinet.

In an embodiment, the housing includes an upper housing and a lower housing that are mated, the upper housing has a protruding end portion protruding from the lower housing on one end thereof, and the protruding end portion is provided with a protrusion extending toward a side where the lower housing is located. The protrusion may be formed as a handle for pushing, pulling and handling the computing node to facilitate manual operation by the staffs. In addition, the protrusion is arranged to extend toward the side where the lower housing is located, and a size of the computing node in an up-down direction (in the vertical direction) may not be increased, which is conducive to saving mounting space.

In a second aspect, the embodiments of the present application provide a computing node. The computing node may be a server and the like. The computing device includes a cabinet and at least one computing node. The cabinet has a mounting member. The computing node is a computing node involved in the first aspect or embodiments of the first aspect, which may be in contact with the mounting member through the rolling assembly. Based on the configuration of the rolling assembly, the push-pull operation of the computing node inside the cabinet is made easier and requires less effort, and the computing node has a longer service life and less susceptible to damage, which is conducive to ensuring normal operation of the computing device within a longer period of time.

### BRIEF DESCRIPTION OF DRAWINGS

FIG. 1 is a structural diagram of an embodiment of a data center;

FIG. 2 is a structural diagram of an embodiment of a cabinet and its internal computing device;

FIG. 3 is a structural diagram of an embodiment of a mounting member;

FIG. 4 is a structural diagram of the mounting member in FIG. 3;

FIG. 5 is a structural diagram of a computing node;

FIG. 6 is a structural diagram of FIG. 5 from another perspective;

FIG. 7 is a sectional view of FIG. 5 in an A-A direction;

FIG. 8 is a partial sectional view of another computing node;

FIG. 9 is a partial sectional view of another computing node;

FIG. 10 is a structural diagram of a lower housing;

FIG. 11 is a partial structural diagram of FIG. 10;

FIG. 12 is a structural diagram of an upper housing; and

FIG. 13 is an exploded view of FIG. 12.

Reference numerals are as follows:
100 data center, 101 computer room;
200 computing device, 201 cabinet, 201a door body, 201b mounting member, 202 computing node;
1 housing, 11 upper housing, 111 body, 111a first reinforcing rib, 111b protruding end portion, 111b-1 protrusion, 111c second avoidance portion, 112 second reinforcing rib, 12 lower housing, 121 bottom plate, 121a bottom support surface, 121b offset surface, 121c first notch groove, 121c-1 first front end wall, 121d first avoidance portion, 122 side plate, 122a groove, 122b second notch groove, 122b-1 second front end wall, 123 front plate, 124 rear plate, 125 partition plate, 126 self-locking buckle, 13 sealing assembly, 14 main cavity, 15 accommodation space, 151 power signal chamber, 151a power cable, 151b power connector, 152 high-speed signal chamber, 152a high-speed signal cable, 152b high-speed signal connector, 153 working medium inlet pipe, 154 working medium outlet pipe, 155 insertion guide assembly, 156 pressure relief valve, 157 signal connector, 16 sheet metal member; and
2 rolling assembly, 21 roller shaft, 22 roller, 2a rolling plane.

### DESCRIPTION OF EMBODIMENTS

In order to make those skilled in the art better understand the technical solution in the present application, the present application is provided in conjunction with accompanying drawings and embodiments.

In the embodiments of the present application, the terms “first” and “second” are used only for descriptive purposes, and should not be interpreted as indicating or implying relative importance or implicitly specifying a quantity of the technical features indicated. Thus, features defined by “first” and “second” may explicitly or implicitly include one or more of such features.

In the embodiments of the present application, “a plurality of” represents two or more; and when “a plurality of” is used to indicate a quantity of several components, it does not represent a relational relationship among these components in terms of quantity.

In the description of the embodiments of the present application, it should be noted that, unless otherwise specified and limited, terms “mounted”, “interconnected” and “connected” are to be understood in a broad sense. For example, “connected” may be detachably connected or non-detachably connected, or may be directly connected or indirectly connected by an intermediate medium.

In the description of the embodiments of the present application, terms “comprising”, “including” or any other variations thereof are intended to cover non-exclusive inclusions, such that a process, method, article, or apparatus that includes a series of elements not only includes those elements, but also includes other elements that are not expressly listed, or further includes elements inherent to the process, method, article, or apparatus. In the absence of additional limitations, elements limited by the sentence “comprising a . . . ” does not exclude the presence of additional identical elements in the process, method, article, or apparatus that includes the elements.

In the embodiments of the present application, “and/or” only refers to an association relationship between association objects, indicating that three relationships may exist. For example, A and/or B may represent: A exists independently, A and B exist simultaneously, and B exists independently. In addition, the character “/” in the context generally indicates that the association objects are in an “or” relationship.

With rapid development of communication technology, Internet service providers, enterprises, research institutions, and others generally start to build data centers (also known as computing clusters) that serve as bearers for storage, computing, and transmission functions to meet the demand for data usage. There may be various structure forms for a data center.

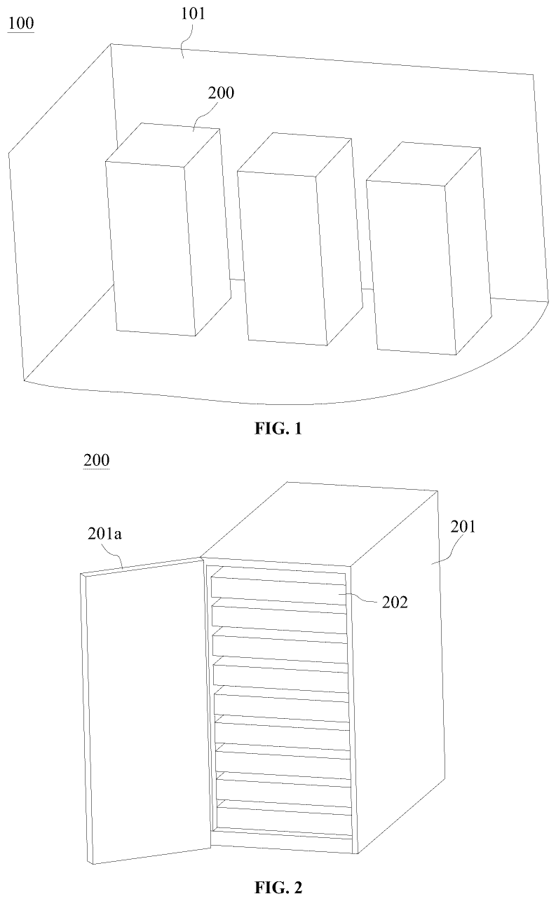

As shown in FIGS. 1 and 2, FIG. 1 is a structural diagram of an embodiment of a data center, and FIG. 2 is a structural diagram of an embodiment of a cabinet and its internal computing device.

As shown in FIG. 1, in some embodiments, the data center 100 may include a computer room 101 and at least one computing device 200. The computer room 101 is used for providing an isolation environment for the data center 100 to isolate the computing device 200 from the outside world. The computer room 101 may be a permanent house, or a temporary shelter such as a tent or prefab house, or a carrier capable of providing an accommodation space such as a container or cargo box. In some applications, at least one side wall of the computer room 101 may be provided with an entrance/exit door to facilitate staffs and others access to the data center 100. There is no limitation on a structure model, open/closing mode, or opening/closing control policy of the entrance/exit door, as long as the technical effect that the staffs enter and exit the data center 100 is achieved.

In some embodiments, the data center 100 is also equipped with an air-cooling circulation system (not shown in the figure) that ventilates and cools the interior of the computer room 101 by configuring at least one air conditioning device or fan device, so as to ensure internal environment and temperature of the computer room 101.

In combination with FIG. 2, the computing device 200 includes a cabinet 201. A mounting space is formed in the cabinet 201, and is used for assembling a computing node 202. The computing device 200 may be a server, and correspondingly, the computing node 202 may be a server node. In some embodiments, there may be a plurality of computing nodes 202, and each computing node 202 may be located at different positions in the cabinet 201. For example, each computing node 202 may be distributed layer by layer inside the cabinet 201. In some embodiments, there may also be one computing node 202. In this case, the computing node 202 may be referred to as a server.

The cabinet 201 may be configured with a door body 201a. When the door body 201a is in an open state, the interior of computing device 200 may be in an exposed state, to facilitate mounting, overhaul, replacement and maintenance of each computing node 202. A quantity of the door bodies 201a may not be limited, which is associated with a structure model and a dimension of the computing node 202. An opening and closing mode of the door body 201a includes, but is not limited to, rotational opening and closing, sliding opening and closing, rolling opening and closing and the like. A lock component matched with the door body 201a may refer to related art, and is not limited here.

The cabinet 201 may be provided with a mounting member for achieving support and assembly of the computing node 202 in the cabinet 201. There may be various structure forms of the mounting member, as long as the mounting member meets usage requirements, which is not limited in embodiments of the present disclosure.

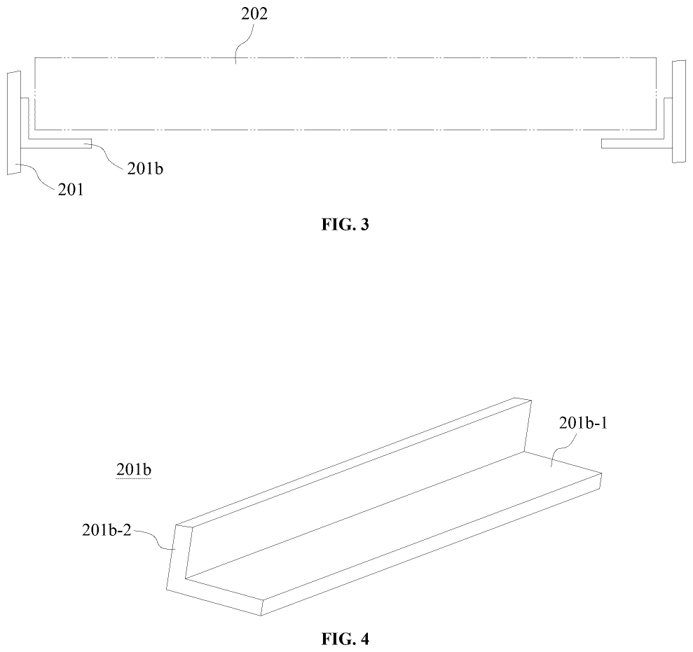

As shown in FIGS. 3 and 4, FIG. 3 is a structural diagram of an embodiment of a mounting member, and FIG. 4 is a structural diagram of the mounting member in FIG. 3.

As shown in FIG. 3, in an example embodiment, a mounting member 201b may be an L-shaped plate member, and includes a horizontal plate portion 201b-1 and a vertical plate portion 201b-2. The vertical plate portion 201b-2 may be mounted on an inner wall of the cabinet 201. The mounting method includes but is not limited to welding, screw connection, riveting, and snap-fitting, as long as mounting reliability can be ensured. The horizontal plate portion 201b-1 may provide support for the computing node 202, and space between two horizontal plate portions 201b-1 may be used to form an air duct for heat dissipation of the computing node 202.

It should be understood that in some scenarios, a structure of the computing node 202 may also be designed so that the computing node 202 may occupy the space between the two horizontal portions 201b-1. This allows for more efficient use of space inside the cabinet 201, thereby increasing integration of the device.

In some other variations, the two horizontal plate portions 201b-1 may also be an integrated structure, that is, the mounting member 201b may also generally be U-shaped. In this case, if a heat dissipation requirement exists, a hollow structure may also be disposed on a bottom plate of the mounting member 201b; alternatively, the mounting member 201b may also directly adopt a plate member and be secured inside the cabinet 201 by means of methods such as welding, insertion or screw connection, which is also feasible.

A plurality of connection interfaces may be provided inside the cabinet 201, and are used for connecting the computing node 202. The connection interfaces include, but are not limited to, power interfaces, high-speed signal structures, cooling working medium interfaces and the like.

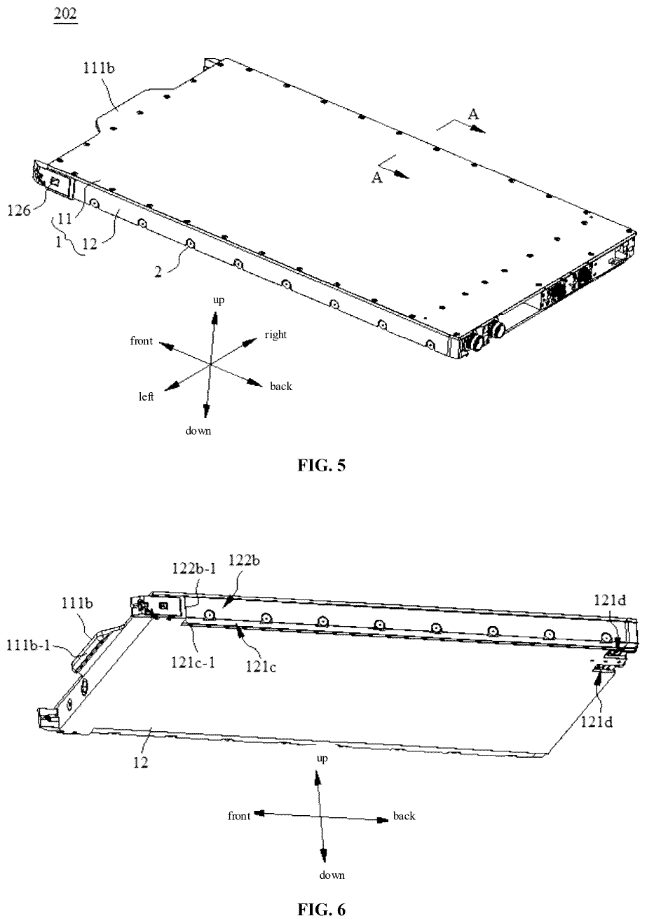

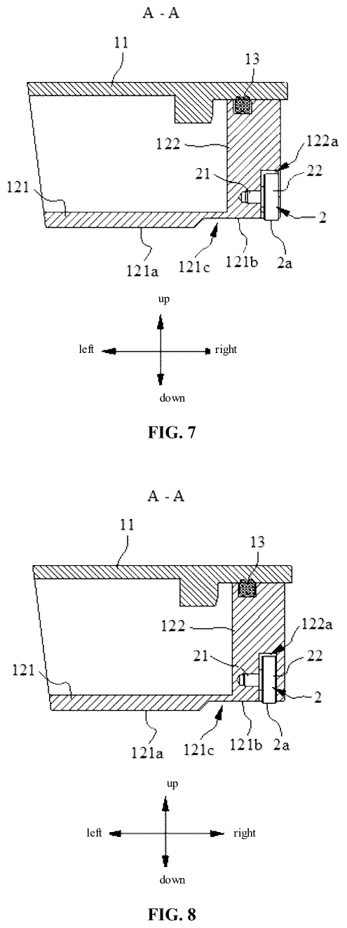

As shown in FIGS. 5 to 7, FIG. 5 is a structural diagram of a computing node, FIG. 6 is a structural diagram of FIG. 5 from another perspective, and FIG. 7 is a sectional view of FIG. 5 in an A-A direction.

As shown in FIGS. 5 and 6, the computing node 202 includes a housing 1 having an internal cavity where an electronic component in the form of a processor is mounted. The housing 1 as a whole may be cuboid-shaped.

For ease of description, “front”, “back”, “up”, “down”, “left”, and “right” directions may be defined by taking directions and positional relations in FIG. 4 for example. A front-back direction is a mounting direction of the computing node 202, where a motion of controlling the computing node 202 to move further into the cabinet 201 is considered as a backward motion, and a motion of controlling the computing node 202 to gradually move out of the cabinet 201 is considered as a forward motion. The computing node 202 may move along the front-back direction in the cabinet 201. In some embodiments, the front-back direction is also referred to as a length direction or a longitudinal direction. In combination with FIG. 2, an up-down direction is a direction in which each computing node 202 is stacked in the cabinet 201. In some embodiments, the up-down direction is also referred to as a height direction, a thickness direction, or a vertical direction. A direction perpendicular to the up-down direction and the front-back direction is a left-right direction. In some embodiments, the left-right direction is also referred to as a width direction or a horizontal direction.

As shown in FIG. 7, a plurality of rolling assemblies 2 are disposed on two horizontal sides of the housing 1. Each of the rolling assemblies 2 is capable of rolling in a same rolling plane 2a. In combination with FIG. 3, the rolling plane 2a may be an upper surface of the horizontal plate portion 201b-1; the computing node 202 can roll on the mounting member 201b by the rolling assembly 2, thereby achieving insertion assembly and pull-out of the computing node 202 inside the cabinet 201. Compared with a conventional drawer slide solution, the rolling assembly 2 in the solution has a simpler structure and is less prone to damage, offering higher reliability and ensuring normal operation of the computing node 202 within a longer period. In addition, compared with a sliding solution, force that drives the rolling assembly 2 to roll in the solution may be smaller, thereby facilitating pushing and pulling the computing node 202.

A quantity of the rolling assemblies 2 disposed on the two horizontal sides of the housing 1 is not specified, and needs to be determined in combination with a size of the computing node 202 in the front-back direction and weight of the computing node. In the embodiment of FIGS. 5 and 6, eight rolling assemblies 2 are disposed on the two horizontal sides of the housing 1.

The housing 1 includes a bottom plate 121 having a bottom support surface 121a. Or, in the up-down direction, the bottom support surface 121a may be lower than the rolling plane 2a. Thus, when the computing node 202 is placed on a desk or a working table (that is, not assembled in the cabinet 201), the rolling assemblies 2 are not in contact with the desk or the operating table, which is conducive to ensuring stable placement of the computing node 202. In an embodiment, the bottom support surface 121a and the rolling plane 2a may be parallel, or may be arranged with an angle formed therebetween; in the solution where the bottom support surface 121a and the rolling plane 2a are arranged with an angle formed therebetween, an included angle value between the bottom support surface 121a and the rolling plane 2a is not limited here.

It should be understood that, the bottom support surface 121a and the rolling plane 2a may also be coplanar. In an embodiment, when the computing node 202 is placed on the desk or the operating table, although the rolling assembly 2 is not in contact with the desk or the operating table, the housing 1 may still be stably placed due to static friction between the bottom support surface 121a and the desk or the operating table.

As still shown in FIG. 3, the housing 1 may further include two side plates 122, the two side plates 122 may be disposed opposite to each other in a horizontal direction (e.g., a left-right direction), the side plates 122 are located above the bottom plate 121, and the rolling assembly 2 may be mounted on the side plates 122. The housing 1 may also be provided with a groove 122a. The rolling assembly 2 may include a roller shaft 21 and a roller 22, the roller shaft 21 may be fixedly mounted on the side plate 122, the roller 22 may be mounted on the roller shaft 21 by a bearing or other assembly, and may rotate relative to the roller 21, so as to drive the computing node 202 to move inside the cabinet 201. It should be understood that the roller shaft 21 may also be fixedly assembled with the roller 22. In this case, the roller 21 may be mounted on the side plate 122 by a bearing or other assembly, so as to achieve relative rotation of the roller 21 and the side panel 122, thereby achieving movement of the computing node 202 in the cabinet 201. In the horizontal direction, the roller 22 may be partially or completely mounted in the groove 122a. In this way, the setting of the rolling assembly 2 can occupy relatively less horizontal space of the computing node 202, and a horizontal dimension of the housing 1 can be made larger. Accordingly, the internal capacity of the housing 1 can also be increased, a quantity or a size of electronic components that can be accommodated in the housing 1 can also be increased, and computing power of the computing node 202 can also be improved.

The bottom plate 121 may have a bottom wall surface. The bottom wall surface includes a bottom support surface 121a and two offset surfaces 121b. The two offset surfaces 121b may be located on two vertical sides of the bottom support surface 121a, the groove 122a has a lower end opening, the lower end opening may be located on each of the offset surfaces 121b; and the bottom support surface 121a may be lower than the offset surfaces 121b, and the rolling plane 2a may be lower than the offset surfaces 121b. In this way, the roller 22 may protrude downward from the offset surfaces 121b and smoothly be in contact with the mounting member 201b, thereby realizing movement of the computing node 202 in the cabinet 201.

Based on an offset configuration of the offset surfaces 121b and the bottom support surface 121a in the up-down direction, the bottom plate 121 may form first notch grooves 121c on two horizontal sides. The configuration, on one hand, can accommodate mounting of the rolling assembly 2 to ensure contact between the rolling assembly 2 and the mounting member 201b; and on the other hand, can also reduce material consumption and weight of the housing 1, thereby facilitating the push-pull operation of the computing node 202. At the same time, the configuration can also mount the computing node 202 by fully utilizing space between the two horizontal plate portions 201b-1, thereby improving integration of the device.

In combination with FIG. 6, the first notch groove 121c can extend forward from the rear end of the housing 1 and does not penetrate the entire housing 1 in a front-back direction. In this way, the first notch groove 121c can have a first front end wall 121c-1, and projection of the mounting member 201b in the front-back direction can fall on the first front end wall 121c-1. In this way, the first front end wall 121c-1 can be used as a limiting assembly to form a stopper with the mounting member 201b to limit an insertion depth of the computing node 202 in the cabinet 201, and can reduce collision force between the computing node 202 and an internal connection interface of the cabinet 201, which is beneficial to protecting the connection interface, thereby improving a service life of the connection interface. Similarly, the side plate 122 may also be provided with a second notch groove 122b similar to the first notch groove 121c. The second notch groove 122b can extend from back to front and does not penetrate the side plate 122, so that the second notch groove 122b can have a second front-end wall 122b-1. The second front-end wall 122b-1 can also cooperate with the mounting member 201b, thereby defining the insertion depth of the computing node 202.

It should be understood that the first notch groove 121c and the second notch groove 122b may be optionally provided; or, the first notch groove 121c and the second notch groove 122b may also be through grooves that penetrate along a front-back direction.

As shown in FIG. 7, the groove 122a may extend in a horizontal direction to a horizontal outer wall surface of the side plate 122. In other words, the groove 122a may also have a side end opening, and the side end opening may be located on the horizontal outer wall surface of the side plate 122, so that mounting of the rolling assembly 2 may be relatively easy. The horizontal outer wall surface refers to a wall surface of the side plate 122 away from an internal cavity of the housing 1 in a horizontal direction; in the structure shown in FIG. 7, the horizontal outer wall surface refers to a right wall surface of the side plate 122.

A horizontal dimension of the roller 22 may be less than or equal to that of the groove 122a; and in a horizontal direction, the roller 22 may be assembled in the groove 122a. In this way, the roller 22 does not protrude from the horizontal outer wall surface of the side plate 122, and the arrangement of the roller 22 does not occupy horizontal space of the housing 1, which can maximize the internal capacity of the housing 1, facilitate mounting of more electronic components or larger electronic components, and thus improve performance of the computing node 202.

As shown in FIG. 8, FIG. 8 is a partial sectional view of another computing node.

As shown in FIG. 8, the groove 122a may also be provided in a horizontal middle area of the side plate 122. In this case, the groove 122a does not extend to the horizontal outer wall surface of the side plate 122, and mounting of the roller 22 also does not occupy a horizontal space of the housing 1. In an embodiment, in order to achieve mounting of the rolling assembly 2, the side plate 122 or the bottom plate 121 may be configured as a split structure.

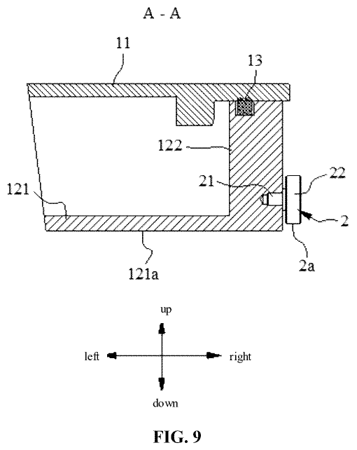

As shown in FIG. 9, FIG. 9 is a partial sectional view of another computing node.

In fact, the groove 122a may also not exist. As shown in FIG. 9, the roller 22 may be directly mounted on the horizontal outer wall side (that is, one side away from the internal cavity) of the side plate 122. In this case, the bottom plate 121 may also be not provided with the offset surfaces 121b and the first notch groove 121c. A structure form of the bottom plate 121 may be relatively simple. Of course, in the solution, the offset surfaces 121b may also be provided.

As shown in FIGS. 5 to 9, the housing 1 may include an upper housing 11 and a lower housing 12. The upper housing 11 and the lower housing 12 may be mated in an up-down direction and fixedly connected by screw connection, clamping and the like. After being mated, the upper housing 11 and the lower housing 12 may be enclosed to form the internal cavity.

In order to ensure effective heat dissipation of the electronic component in the housing 1, a cooling working medium is also filled in the internal cavity of the housing 1. The cooling working medium may be a liquid phase working medium or a two-phase working medium. In order to avoid leakage of the cooling working medium, a sealing assembly 13 is also configured at a joint of the upper housing 11 and the lower housing 12. The sealing assembly 13 may be a rubber ring or the like.

In some embodiments, internal space of the internal cavity may be formed by the lower housing 12, in which case the upper housing 11 is only equivalent to a cover body. Of course, the internal space of the internal cavity may also be formed by the upper housing 11, in which case the lower housing 12 is also equivalent to the cover body. In other embodiments, both the upper housing 11 and the lower housing 12 may form cavity space extending in the up-down direction, and after the upper housing 11 and the lower housing 12 are mated, cavity space of the upper housing 11 and cavity space of the lower housing 12 may be in communication with each other to form an internal cavity of the housing 1. The two implementations may be adopted in specific practice.

For ease of understanding, the following embodiments of the present application are described by taking the internal space of the internal cavity formed by the lower housing 12 for example. In addition, for ease of description, in the following related descriptions, the internal cavity of the housing 1 is also directly described as the internal cavity of the lower housing 12.

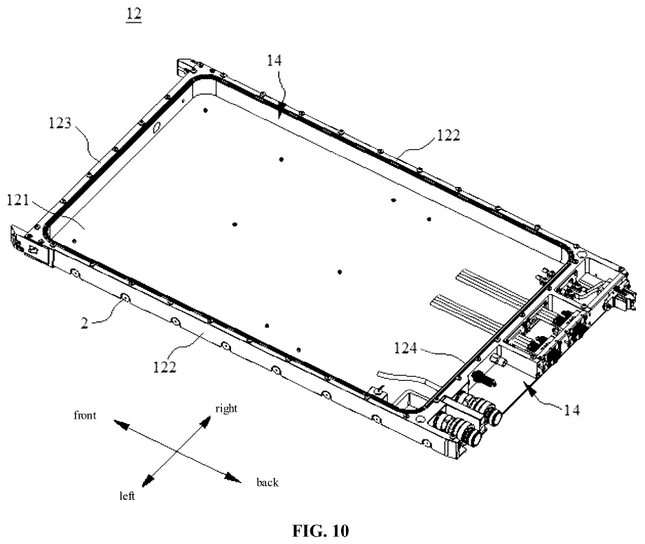

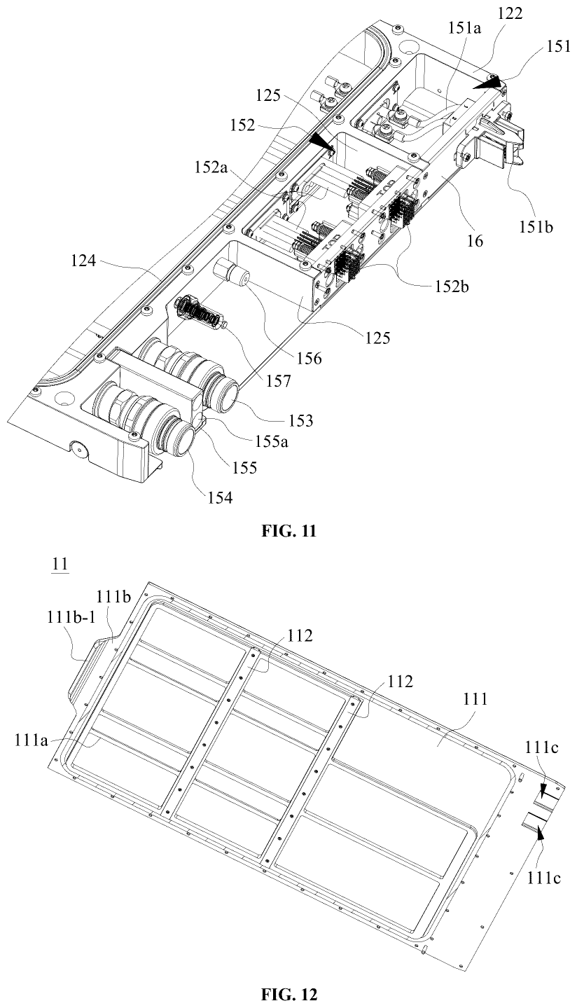

As shown in FIGS. 10 and 11, FIG. 10 is a structural diagram of a lower housing, and FIG. 11 is a partial structural diagram of FIG. 10.

As shown in FIG. 10, the lower housing 12 includes a bottom plate 121, two side plates 122, a front plate 123, and a rear plate 124. The two side plates 122 may be arranged opposite to each other in a left-right direction, and the front plate 123 and the rear plate 124 may be arranged opposite to each other in a front-back direction. The bottom plate 121, the two side plates 122, the front plate 123, and the rear plate 124 may be integrally formed, and for example, may be integrally cast and formed, so as to simplify a preparation process of the lower housing 12; of course, these plates may also be independently manufactured and formed, and then connected by screw connection, welding, riveting, clamping and the like. It should be noted that when a connection method such as screw connection, riveting, clamping and the like that cannot directly form a sealed connection is adopted, a sealing member in the form of a sealing ring or the like needs to be arranged between plates to ensure sealing performance of the lower housing 12.

The rear plate 124 is not disposed at a rear end of the bottom plate 121, so that the rear plate 124 may divide space between the bottom plate 121 and the two side plates 122 into two parts, which are respectively a main cavity 14 enclosed by the front plate 123, the two side plates 122, the rear plate 124 and the bottom plate 121, and an accommodation space 15 enclosed by the rear plate 124, the two side plates 122 and the bottom plate 121. The main cavity 14 may be located at a front side of the accommodation space 15, and the upper housing 11 may cover above the main cavity 14 and the accommodation space 15. The main cavity 14 is configured with an electronic component in the form of a processor and is filled with a cooling working medium used for meeting cooling and heat dissipation requirements of the electronic component; and the accommodation space 15 may be provided with an external connection component used for being connected to a connection interface in the cabinet 201.

By adopting the solution, the upper housing 11 and the lower housing 12 can protect the external connection component in the accommodation space 15, which can reduce damage to the external connection component during transportation and handling, and can also improve structural strength of the entire housing 1, and the appearance design of the housing 1 is also neater.

In combination with FIG. 11, two partitions 125 extending in the front-back direction may also be configured in the accommodation space 15. The two partitions 125 may be spaced apart in a left-to-right direction to isolate a power signal chamber 151 and a high-speed signal chamber 152 that are isolated from each other in the accommodation space 15. The power signal chamber 151 is provided with a power cable 151a, and the high-speed signal chamber 152 is provided with a high-speed signal cable 152a. The power cable 151a and the high-speed signal cable 152a are both the external connection components.

In some embodiments, the housing 1 may also be provided with a sheet metal member 16. The sheet metal member 16 may be connected to the partitions 125 and the side plate 122, to form rear walls of the power signal chamber 151 and the high-speed signal chamber 152, thereby enhancing structural strength of the power signal chamber 151 and the high-speed signal chamber 152. It should be understood that the rear walls of the power signal chamber 151 and the high-speed signal chamber 152 may also be independent of each other, that is, two sheet metal members 16 may be provided. The two sheet metal members 16 may respectively form the rear wall of the power signal chamber 151 and the rear wall of the high-speed signal chamber 152.

The rear wall of the power signal chamber 151 may be provided with a power connector 151b, and the power cable 151a may be connected to the power connector 151b. The rear wall of the high-speed signal chamber 152 may be provided with a high-speed signal connector 152b, and the high-speed signal cable 152a may be connected to the high-speed signal connector 152b.

The external connection component may further include a working medium inlet pipe 153 and a working medium outlet pipe 154. The working medium inlet pipe 153 and the working medium outlet pipe 154 may be mounted on the rear plate 124, to achieve circulation of the cooling working medium in the main cavity 14.

In combination with FIG. 6, a first avoidance portion 121d may also be provided on the bottom plate 121 of the lower housing 12, and a setting position of the first avoidance portion 121d may correspond to a mounting position of the working medium inlet pipe 153 and the working medium outlet pipe 154, so that the working medium inlet pipe 153 and the working medium outlet pipe 154 may be partially located in the first avoidance portion 121d, thereby reducing a size of the housing 1 in the up-down direction. The first avoidance portion 121d may be a hole-type structure that penetrates the bottom plate 121 in the up-down direction, or may be a groove-type structure that does not penetrate the bottom plate 121 from top to bottom.

The accommodation space 15 may also be provided with an insertion guide assembly 155 for guiding an assembly direction of the computing node 202. A structure of the insertion guide assembly 155 is not limited in the embodiments of the present application. In practical applications, those skilled in the art may configure a structure of the insertion guide assembly 155 based on a structure of a guide matching assembly provided in the cabinet 201, as long as the technical effect of insertion guidance can be achieved. For example, as shown in FIG. 11, the insertion guide assembly 155 may be provided with a guide hole 155a, and the guide matching assembly inside the cabinet 201 may be a guide column and the like. When the computing node 202 is inserted, the guide column may be inserted into the guide hole 155a.

In some embodiments, a pressure relief valve 156 and a signal connector 157 may also be provided in the accommodation space 15, and the external connection component includes the pressure relief valve 156 and the signal connector 157. The pressure relief valve 156 is used to open when pressure in the main cavity 14 is too high, so as to reduce the pressure in the main cavity 14, thereby improving safety performance, and the signal connector 157 is used for an external signal cable.

In combination with FIG. 5, a front end of the lower housing 12 may be provided with a self-locking buckle 126, and the self-locking buckle 126 can cooperate with the cabinet 201 to achieve mounting and fixation of the computing node 202 inside the cabinet 201. A structure of the self-locking buckle 126 is not limited here, and in practical applications, may be determined by those skilled in the art based on the related art. It shall be understood that the self-locking buckle 126 may also be provided on the upper housing 11, as long as the self-locking function can be achieved.

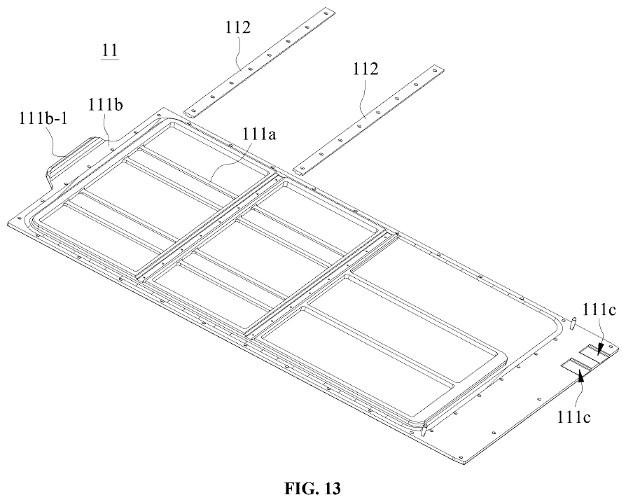

As shown in FIGS. 12 and 13, FIG. 12 is a structural diagram of an upper housing, and FIG. 13 is a partial structural diagram of FIG. 12.

As shown in FIGS. 12 and 13, the upper housing 11 includes a body 111, which is basically a plate-like structure, and a plurality of first reinforcing ribs 111a are provided on one side toward the main cavity 14 to improve structural strength of the body 111. The body 111 may generally be made of aluminum alloy or the like.

In some embodiments, the upper housing 11 may also include a second reinforcing rib 112. The second reinforcing rib 112 may be made of a material with higher structural strength such as steel. The second reinforcing rib 112 may be mounted and fixed to the body 111 by a connector in the form of a screw and the like, so as to further improve structural strength of the upper housing 11.

In combination with FIGS. 4 and 6, the front end of the upper housing 11 has a protruding end portion 111b protruding from the lower housing 12, and the protruding end 111b may be configured with a protrusion 111b-1 extending downward. Since the protrusion 111b-1 is arranged to extend downward, a size of the computing node 202 in the up-down direction may not be increased, which is conducive to saving mounting space. At the same time, the protrusion 111b-1 may be used as a handle for pushing, pulling and handling the computing node 202 to facilitate manual operation by the staffs.

In some embodiments, a second avoidance portion 111c may also be provided on the upper housing 11. A setting position of the second avoidance portion 111c may correspond to a mounting position of the working medium inlet pipe 153 and the working medium outlet pipe 154, so that the working medium inlet pipe 153 and the working medium outlet pipe 154 may be partially located in the second avoidance portion 111c, thereby reducing the size of the housing 1 in an up-down direction. The second avoidance portion 111c may be a hole-type structure that penetrates the upper housing 11 in the up-down direction, or may be a groove-type structure that does not penetrate the upper housing 11 from bottom to top.

The above are only embodiments of the present application. It should be noted that for those skilled in the art, a plurality of improvements and modifications can be made without departing from the principles of the present application. These improvements and modifications should also be considered to be within the protection scope of the present application.

What is claimed is:

1. A computing node, comprising:
a housing, wherein the housing comprises:
two side plates disposed opposite to each other in a horizontal direction, wherein each of the two side plates is provided with a plurality of rolling assemblies, and each of the rolling assemblies is capable of rolling in a rolling plane; and
a bottom plate having a bottom support surface, wherein the bottom support surface and the rolling plane are coplanar or in a vertical direction, and the bottom support surface is lower than the rolling plane.

2. The computing node according to claim 1, wherein the bottom plate comprises a bottom wall surface, the bottom wall surface comprises the bottom support surface and two offset surfaces, the two offset surfaces are located on two horizontal sides of the bottom support surface, the bottom support surface is lower than the offset surfaces, and the rolling plane is lower than the offset surfaces.

3. The computing node according to claim 2, wherein the housing comprises a groove, the rolling assembly comprises a roller, and the roller is mounted in the groove.

4. The computing node according to claim 3, wherein the groove comprises:
a lower end opening disposed on the offset surface; and
a side end opening disposed on a horizontal outer wall surface of the side plate.

5. The computing node according to claim 4, wherein a horizontal dimension of the roller is less than or equal to that of the groove; and in a horizontal direction, the roller is assembled in the groove.

6. The computing node according to claim 3, wherein the groove comprises a lower end opening disposed on the offset surface.

7. The computing node according to claim 1, wherein the housing further comprises:
a main cavity; and
an accommodation space isolated from the main cavity, disposed on one side of the main cavity in a plugging direction of the computing node, and is configured with an external connection component.

8. The computing node according to claim 7, wherein the accommodation space comprises a power signal chamber and a high-speed signal chamber that are isolated from each other, the external connection component comprises a power cable and a high-speed signal cable, the power cable is disposed in the power signal chamber, and a rear wall of the power signal chamber is provided with a power connector, the high-speed signal cable is disposed in the high-speed signal chamber, and a rear wall of the high-speed signal chamber is provided with a high-speed signal connector.

9. The computing node according to claim 7, wherein the main cavity is filled with a cooling working medium, and the accommodation space is further provided with a working medium inlet pipe and a working medium outlet pipe.

10. The computing node according to claim 7, wherein the accommodation space is further provided with an insertion guide assembly.

11. The computing node according to claim 1, wherein the housing further comprises an upper housing and a lower housing that are mated, the upper housing has a protruding end portion that protrudes from the lower housing on one end thereof, and the protruding end portion is provided with a protrusion that extends toward a side where the lower housing is located.

12. The computing node according to claim 1, wherein the housing comprises an avoidance portion on two plate bodies that are disposed opposite to each other in the vertical direction, the avoidance portion provides avoidance for a working medium inlet pipe and a working medium outlet pipe.

13. A computing device, comprising:
a cabinet having a mounting member; and
a computing node, comprising:
a housing, wherein the housing comprises:
two side plates disposed opposite to each other in a horizontal direction, wherein each of the two side plates is provided with a plurality of rolling assemblies, and each of the rolling assemblies is capable of rolling in a rolling plane; and
a bottom plate having a bottom support surface, wherein the bottom support surface and the rolling plane are coplanar or in a vertical direction, and the bottom support surface is lower than the rolling plane, and wherein at least one of the rolling assemblies is in contact with the mounting member.

14. The computing device according to claim 13, wherein the bottom plate comprises a bottom wall surface, the bottom wall surface comprises the bottom support surface and two offset surfaces, the two offset surfaces are located on two horizontal sides of the bottom support surface, the bottom support surface is lower than the offset surfaces, and the rolling plane is lower than the offset surfaces.

15. The computing device according to claim 14, wherein the housing comprises a groove, the rolling assembly comprises a roller, and the roller is mounted in the groove.

16. The computing device according to claim 15, wherein the groove comprises:
a lower end opening disposed on the offset surface; and
a side end opening disposed on a horizontal outer wall surface of the side plate.

17. The computing device according to claim 16, wherein a horizontal dimension of the roller is less than or equal to that of the groove; and in a horizontal direction, the roller is assembled in the groove.

18. The computing device according to claim 15, wherein the groove comprises a lower end opening disposed on the offset surface.

19. The computing device according to claim 13, wherein the housing further comprises:
a main cavity; and
an accommodation space isolated from the main cavity, disposed on one side of the main cavity in a plugging direction of the computing node, and is configured with an external connection component.

20. The computing device according to claim 19, wherein the accommodation space comprises a power signal chamber and a high-speed signal chamber that are isolated from each other, the external connection component comprises a power cable and a high-speed signal cable, the power cable is disposed in the power signal chamber, and a rear wall of the power signal chamber is provided with a power connector, the high-speed signal cable is disposed in the high-speed signal chamber, and a rear wall of the high-speed signal chamber is provided with a high-speed signal connector.
